(19) United States
(12) Patent Application Publication
(10) Pub. No.: US 2026/0164790 A1
(43) Pub. Date: Jun. 11, 2026

(54) SEMICONDUCTOR ELEMENT

(71) Applicant: Japan Display Inc., Tokyo (JP)

(72) Inventor: Masumi NISHIMURA, Tokyo (JP)

(73) Assignee: Japan Display Inc., Tokyo (JP)

(21) Appl. No.: 19/179,021

(22) Filed: Apr. 15, 2025

Related U.S. Application Data
(63) Continuation of application No. PCT/JP2023/039860, filed on Nov. 6, 2023.

(30) Foreign Application Priority Data
Nov. 30, 2022 (JP) 2022-191821

(51) Int. Cl. H10D 86/00; H10D 30/47; H10D 62/824; H10W 20/41

(52) U.S. Cl. CPC H10D 86/00; H10D 30/475; H10W 20/435; H10D 62/824

(57) ABSTRACT

A semiconductor element includes a first transistor and a second transistor over an amorphous substrate. The first transistor includes a buffer layer, a first nitride semiconductor layer over the buffer layer, a second nitride semiconductor layer forming a heterojunction with the first nitride semiconductor layer, and a first conductive layer in contact with the second nitride semiconductor layer and functioning as a source electrode or a drain electrode. The second transistor includes a non-nitride semiconductor layer, and a second conductive layer in contact with the non-nitride semiconductor layer and functioning as a source electrode or a drain electrode. The first conductive layer is electrically connected to the second conductive layer.

### CROSS-REFERENCE TO RELATED APPLICATIONS

This application is a Continuation of International Patent Application No. PCT/JP2023/039860, filed on Nov. 6, 2023, which claims the benefit of priority to Japanese Patent Application No. 2022-191821, filed on Nov. 30, 2022, the entire contents of which are incorporated herein by reference.

### FIELD

An embodiment of the present invention relates to a semiconductor device including a transistor using a compound semiconductor, in particular, a high electron mobility transistor (HEMT).

### BACKGROUND

Gallium nitride (GaN) is a direct bandgap semiconductor with a large bandgap. Focusing on the properties of gallium nitride, gallium nitride has the characteristics of high saturated electron mobility and a high breakdown voltage. In recent years, a transistor for a high-frequency power device, that is, a HEMT, has been developed by utilizing the characteristics of gallium nitride.

The HEMT has a heterojunction structure in which not only gallium nitride but also aluminum gallium nitride (AlGaN) is provided in contact with the gallium nitride. At the interface between the gallium nitride and the aluminum gallium nitride, charges are induced by the spontaneous polarization of the gallium nitride functioning as the semiconductor layer and the piezoelectric effect of the aluminum gallium nitride functioning as the polarization layer, so that a high-density two-dimensional electron gas (2DEG) is formed. Since the concentration of the two-dimensional electron gas in the HEMT is large and the saturated electron mobility is also high, high-speed operation in the HEMT is possible.

Gallium nitride in a HEMT is generally formed on a sapphire substrate at a high temperature of 800 degrees to 1000 degrees using MOCVD (Metal Organic Chemical Vapor Deposition) or HVPE (Hydride Vapor Phase Epitaxy).

### SUMMARY

A semiconductor element according to an embodiment of the present invention includes a first transistor and a second transistor over an amorphous substrate. The first transistor includes a buffer layer, a first nitride semiconductor layer over the buffer layer, a second nitride semiconductor layer forming a heterojunction with the first nitride semiconductor layer, and a first conductive layer in contact with the second nitride semiconductor layer and functioning as a source electrode or a drain electrode. The second transistor includes a non-nitride semiconductor layer, and a second conductive layer in contact with the non-nitride semiconductor layer and functioning as a source electrode or a drain electrode. The first conductive layer is electrically connected to the second conductive layer.

### BRIEF DESCRIPTION OF DRAWINGS

FIG. 1 is a schematic cross-sectional view showing a configuration of a semiconductor element according to an embodiment of the present invention.

FIG. 2 is a circuit diagram showing a circuit configuration of a semiconductor element according to an embodiment of the present invention.

FIG. 3 is a schematic cross-sectional view showing a configuration of a semiconductor element according to an embodiment of the present invention.

FIG. 4 is a schematic cross-sectional view showing a configuration of a semiconductor element according to an embodiment of the present invention.

FIG. 5 is a schematic cross-sectional view showing a configuration of a semiconductor element according to an embodiment of the present invention.

FIG. 6 is a schematic cross-sectional view showing a configuration of a semiconductor element according to an embodiment of the present invention.

FIG. 7 is a schematic cross-sectional view showing a configuration of a semiconductor element according to an embodiment of the present invention.

FIG. 8 is a schematic cross-sectional view showing a configuration of a semiconductor element according to an embodiment of the present invention.

FIG. 9 is a schematic cross-sectional view showing a configuration of a semiconductor element according to an embodiment of the present invention.

FIG. 10 is a schematic cross-sectional view showing a configuration of a semiconductor element according to an embodiment of the present invention.

FIG. 11 is a schematic cross-sectional view showing a configuration of a semiconductor element according to an embodiment of the present invention.

### DESCRIPTION OF EMBODIMENTS

In general, although gallium nitride is deposited on a sapphire substrate at a high temperature, it is difficult to increase the area of the sapphire substrate, and therefore it is difficult to reduce manufacturing costs. Therefore, the technology has been developed in which a buffer layer (an alignment layer) controlling a c-axis orientation of gallium nitride is provided on an amorphous substrate such as a glass substrate that is capable of having a large-area and the gallium nitride is deposited by sputtering at a low temperature. However, there is a problem that a HEMT easily has a normally-on type (depression type) property.

In view of the above problems, an embodiment of the present invention can provide a semiconductor element having a structure that suppresses a normally-on type property of a HEMT and has a high freedom in design.

Hereinafter, each of the embodiments of the present invention is described with reference to the drawings. Each of the embodiments is merely an example, and a person skilled in the art could easily conceive of the invention by appropriately changing the embodiment while maintaining the gist of the invention, and such changes are naturally included in the scope of the invention. For the sake of clarity of the description, the drawings may be schematically represented with respect to the widths, thicknesses, shapes, and the like of the respective portions in comparison with actual embodiments. However, the illustrated shapes are merely examples and are not intended to limit the interpretation of the present invention.

In the present specification, the expression “a includes A, B, or C,” “a includes any of A, B, or C,” “a includes one selected from a group consisting of A, B and C,” and the like does not exclude the case where a includes a plurality of combinations of A to C unless otherwise specified. Further, these expressions do not exclude the case where a includes other components.

In the present specification, although the phrase “on” or “over” or “under” or “below” is used for convenience of explanation, in principle, the direction from a substrate toward a structure is referred to as “on” or “over” with reference to a substrate in which the structure is formed. Conversely, the direction from the structure to the substrate is referred to as “under” or “below.” Therefore, in the expression of “a structure over a substrate,” one surface of the structure in the direction facing the substrate is the bottom surface of the structure and the other surface is the upper surface of the structure. In addition, the expression of “a structure over a substrate” only explains the vertical relationship between the substrate and the structure, and another member may be placed between the substrate and the structure. Furthermore, the term “on” or “over” or “under” or “below” means the order of stacked layers in the structure in which a plurality of layers is stacked, and may not be related to the position in which layers overlap in a plan view.

In the specification, terms such as “first,” “second,” or “third” attached to each configuration are convenient terms used to distinguish each component, and have no further meaning unless otherwise explained.

In the specification and the drawings, the same reference numerals may be used when multiple components are identical or similar in general, and reference numerals with a lower or upper case letter of the alphabet may be used when the multiple components are distinguished. Further, reference numerals with a hyphen and a natural number may be used when multiple portions of one component are distinguished.

### First Embodiment

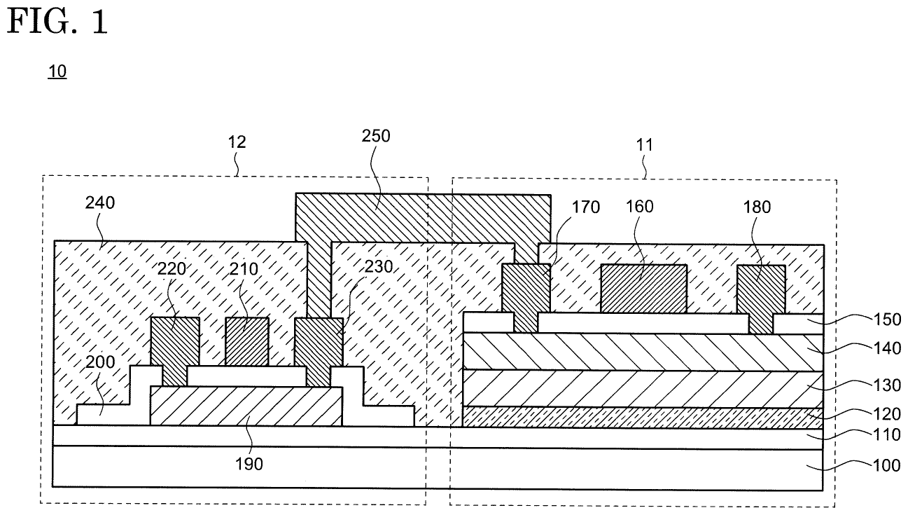

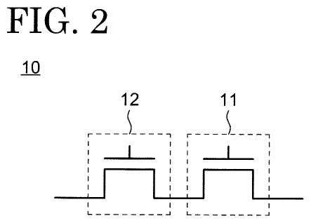

FIG. 1 is a schematic cross-sectional view showing a configuration of a semiconductor element 10 according to an embodiment of the present invention. FIG. 2 is a circuit diagram showing a circuit configuration of the semiconductor element 10 according to an embodiment of the present invention. As shown in FIGS. 1 and 2, the semiconductor element 10 includes a first transistor 11 and a second transistor 12.

### [1. Structural Configuration of Semiconductor Element 10]

The first transistor 11 includes an amorphous substrate 100, a base layer 110, a buffer layer 120, a first nitride semiconductor layer 130, a second nitride semiconductor layer 140, an insulating layer 150, and conductive layers 160, 170, and 180. The base layer 110 is provided on the amorphous substrate 100. The buffer layer 120 is provided on the base layer 110. The first nitride semiconductor layer 130 is provided on the buffer layer 120. The second nitride semiconductor layer 140 is provided on the first nitride semiconductor layer 130. The insulating layer 150 is provided on the second nitride semiconductor layer 140. The conductive layers 160, 170, and 180 are provided on the insulating layer 150. Further, openings are provided in the insulating layer 150, and the conductive layers 170 and 180 are electrically connected to the second nitride semiconductor layer 140 through the openings.

The second transistor 12 includes the amorphous substrate 100, the base layer 110, a non-nitride semiconductor layer 190, an insulating layer 200, and conductive layers 210, 220, and 230. The base layer 110 is provided on the amorphous substrate 100. The non-nitride semiconductor layer 190 is provided on the base layer 110. The insulating layer 200 is provided on the non-nitride semiconductor layer 190, and covers an upper surface and a side surface of the non-nitride semiconductor layer 190. The conductive layers 210, 220, and 230 are provided on the insulating layer 200. Further, openings are provided in the insulating layer 200, and the conductive layers 220 and 230 are electrically connected to the non-nitride semiconductor layer 190 through the openings.

As shown in FIG. 1, the first transistor 11 and the second transistor 12 are provided over the same amorphous substrate 100. The first transistor 11 and the second transistor 12 include the base layer 110 as a common layer. The conductive layers 160, 170, and 180 of the first transistor 11 and the conductive layers 210, 220, and 230 of the second transistor 12 are covered with an insulating layer 240. The insulating layer 240 has an opening through which the conductive layer 170 of the first transistor 11 and the conductive layer 230 of the second transistor 12 are exposed. A conductive layer 250 is provided in the opening, and the conductive layer 170 of the first transistor 11 and the conductive layer 230 of the second transistor 12 are electrically connected to each other through the conductive layer 250. That is, the conductive layer 250 functions as a connection electrode that electrically connects the first transistor 11 and the second transistor 12.

In the first transistor 11, the first nitride semiconductor layer 130 is in contact with the second nitride semiconductor layer 140. Further, the first nitride semiconductor contained in the first nitride semiconductor layer 130 is different from the second nitride semiconductor contained in the second nitride semiconductor layer 140. Therefore, a heterojunction having band discontinuity is formed at the interface between the first nitride semiconductor layer 130 and the second nitride semiconductor layer 140, and a high concentration and high mobility two-dimensional electron gas (2DEG) is generated near the junction interface due to spontaneous polarization and the piezoelectric effect. In other words, the first nitride semiconductor layer 130 and the second nitride semiconductor layer 140 can function as a channel layer and a polarization layer, respectively. That is, the first transistor 11 is a so-called HEMT. The conductive layers 160, 170, and 180 function as a gate electrode, a source electrode, and a drain electrode, respectively. The insulating layer 150 functions as a gate insulating film. In addition, the first transistor 11 may have a structure in which the insulating layer 150 is not provided. In the case where the insulating layer 150 is not provided, the conductive layer 160 is in contact with the second nitride semiconductor layer 140 and functions as a so-called Schottky gate electrode.

On the other hand, the second transistor 12 is a top-gate transistor in which the non-nitride semiconductor layer 190 functions as a channel formation region. The conductive layers 210, 220, and 230 function as a gate electrode, a source electrode, and a drain electrode, respectively. The insulating layer 200 functions as a gate insulating film.

As described above, the conductive layer 170 of the first transistor 11 and the conductive layer 230 of the second transistor 12 are electrically connected to each other. In other words, the source electrode of the first transistor 11 and the drain electrode of the second transistor 12 are electrically connected to each other. Therefore, as shown in FIG. 2, the semiconductor element 10 has a configuration in which the first transistor 11 and the second transistor 12 are connected in series. Specifically, the source electrode of the first transistor 11 and the drain electrode of the second transistor 12 are electrically connected to each other. Alternatively, the drain electrode of the first transistor 11 and the source electrode of the second transistor 12 are electrically connected to each other. In the semiconductor element 10, even when the first transistor 11 (HEMT) has a normally-on type property, the second transistor 12 can function as a switch that can block the off current of the first transistor 11 and control the on or off state of the first transistor 11. Therefore, the semiconductor element 10 can function as a normally-off type (enhancement type) transistor. The gate electrode of the first transistor 11 and the gate electrode of the second transistor 12 may be electrically connected to each other. In this case, the second transistor 12 can be controlled to be turned on or off in accordance with the control of the on or off state of the first transistor 11. The gate electrodes of the first transistor 11 and the second transistor 12 may be controlled separately. In this case, the off-current of the first transistor 11 can be cut off by adjusting the voltage applied to the gate electrode of the second transistor 12.

In general, the mobility of a HEMT is higher than that of a transistor using silicon or an oxide semiconductor as a channel. Therefore, when the second transistor 12 is connected to the first transistor 11, the current of the second transistor 12 becomes dominant, and the current flowing through the semiconductor element 10 may not be equal to the current of the first transistor 11. However, in the semiconductor element 10, the current of the second transistor 12 can be increased by increasing the channel width of the second transistor 12 or by connecting a plurality of second transistors 12 in parallel with the first transistor 11. That is, the decrease in the current flowing through the semiconductor element 10 can be suppressed by adjusting the configuration of the second transistor 12.

### [2. Material Composition of Semiconductor Element 10]

The amorphous substrate 100 is a support substrate for the first transistor 11 and the second transistor 12. Although details are described later, the first nitride semiconductor layer 130 and the second nitride semiconductor layer 140 are deposited by sputtering, so that the amorphous substrate 100 only needs to have heat resistance of, for example, about 600° C. Therefore, for example, an amorphous glass substrate can be used as the amorphous substrate 100. Further, a resin substrate such as a polyimide substrate, an acrylic substrate, a siloxane substrate, or a fluororesin substrate can also be used as the amorphous substrate 100. Such an amorphous glass substrate or resin substrate is a substrate that can be provided with a large area. Therefore, the semiconductor element 10 can be manufactured using a large area substrate.

The base layer 110 can prevent the diffusion of impurities from the amorphous substrate 100 or impurities from the outside (e.g., moisture or sodium (Na)). For example, a silicon nitride (SiNₓ) film or the like can be used as the base layer 110. Further, a laminated film of a silicon oxide (SiOₓ) film and a silicon nitride (SiNₓ) film can be used as the base layer 110.

The buffer layer 120 can control the crystal orientation of the first nitride semiconductor layer 130 formed by sputtering, and can improve the crystallinity of the first nitride semiconductor layer 130. Specifically, the buffer layer 120 can control the crystallinity of the first nitride semiconductor layer 130 so that the first nitride semiconductor layer 130 has a c-axis orientation. For example, in the case where the first nitride semiconductor is gallium nitride, although the gallium nitride having a hexagonal close-packed structure grows in the c-axis direction so as to minimize surface energy, crystal growth of the gallium nitride with the c-axis orientation can be promoted by depositing the gallium nitride on the buffer layer 120. A material having a hexagonal close-packed structure, a face-centered cubic structure, or a structure equivalent thereto can be used for the buffer layer 120. Here, the structure equivalent to the hexagonal close-packed structure or the face-centered cubic structure includes a crystal structure in which the c-axis is not 90 degrees with respect to the a-axis and the b-axis.

The buffer layer 120 with the material having the hexagonal close-packed structure or the structure equivalent thereto can have an orientation in the (0001) direction, that is, in the c-axis direction with respect to the substrate 100 (hereinafter, referred to as the (0001) orientation of the hexagonal close-packed structure). Further, the buffer layer 120 with the material having the face-centered cubic structure or the structure equivalent thereto can have an orientation in the (111) direction with respect to the substrate 100 (hereinafter, referred to as the (111) orientation of the face-centered cubic structure). When the buffer layer 120 has the (0001) orientation of the hexagonal close-packed structure or the (111) orientation of the face-centered cubic structure, the crystal growth of the gallium nitride deposited on the buffer layer 120 in the c-axis direction is promoted and the first semiconductor layer 130 has the c-axis orientation with high crystallinity.

The crystallinity of the first nitride semiconductor layer 130 on the buffer layer 120 is affected by the surface state of the buffer layer 120. Therefore, it is preferable that the buffer layer 120 has a smooth surface with little unevenness. For example, the surface arithmetic mean roughness (Ra) of the buffer layer 120 is preferably less than 2.3 nm. Further, the root mean square roughness (Rq) of the surface of the buffer layer 120 is preferably less than 2.9 nm. When the surface roughness of the buffer layer 120 satisfies the above conditions, the first nitride semiconductor layer 130 has the c-axis orientation with further high crystallinity. In addition, the thickness of the buffer layer 120 is preferably greater than or equal to 50 nm.

A conductive material or an insulating material may be used for the buffer layer 120. The buffer layer 120 can be deposited by any method (apparatus) such as sputtering or CVD.

Titanium (Ti), magnesium (Mg), aluminum (Al), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), or thorium (Th), or an alloy thereof can be used as the conductive material of the first buffer layer 120. Further, titanium nitride (TiNₓ), titanium oxide (TiOₓ), graphene, zinc oxide (ZnO), magnesium diboride (MgB₂), BiLaTiO, SrFeO, BiFeO, BaFeO, ZnFeO, or PMnN-PZT can be used as the conductive material of the buffer layer 120. In particular, it is preferable to use titanium, graphene, or zinc oxide for the buffer layer 120.

Further, silicon (Si), germanium (Ge), or an alloy thereof can be used as the conductive material of the buffer layer 120. Although silicon and germanium are semiconductor materials, they have higher conductivity than insulating materials described later. Therefore, in the present specification, it is described that semiconductor materials such as silicon and germanium used for the buffer layer 120 are included in the conductive material.

Aluminum nitride (AlN), aluminum oxide (Al₂O₃), lithium niobate (LiNbO), BiLaTiO, SrFeO, SrFeO, BiFeO, BaFeO, ZnFeO, PMnN-PZT, or biological apatite (BAp) can be used as the insulating material of the buffer layer 120. In particular, it is preferable to use aluminum nitride for the buffer layer 120.

As described above, the first nitride semiconductor layer 140 and the second nitride semiconductor layer 150 can function as a channel layer and a polarization layer of the HEMT, respectively. Although a compound semiconductor such as gallium nitride (GaN) and aluminum gallium nitride (AlGaN) is used for each of the first nitride semiconductor layer 130 and the second nitride semiconductor layer 140, the material of each of the first nitride semiconductor layer 130 and the second nitride semiconductor layer 140 is not limited to these compound semiconductors. For example, indium nitride (InN), aluminum indium nitride (AlInN), indium gallium nitride (InGaN), or aluminum indium gallium nitride (AlInGaN) can also be used for each of the first nitride semiconductor layer 130 and the second nitride semiconductor layer 140.

Since the first nitride semiconductor layer 130 is formed on the buffer layer 120, the first nitride semiconductor layer 130 has the c-axis orientation with high crystallinity. Further, since the second nitride semiconductor layer 140 is formed on the first nitride semiconductor layer 130 having the c-axis orientation with high crystallinity, the second nitride semiconductor layer 140 also has a c-axis orientation with high crystallinity.

Here, a deposition of gallium nitride using sputtering is described as an example of forming the first nitride semiconductor layer 130.

The amorphous substrate 100 is placed facing a gallium nitride target in a vacuum chamber. It is preferable that the composition ratio of gallium nitride in the gallium nitride target is greater than or equal to 0.7 and less than or equal to 2 of gallium relative to nitrogen. Further, nitrogen can also be supplied to the vacuum chamber as a gas other than a sputtering gas (such as argon (Ar) or krypton (Kr)). In that case, it is preferable that the composition ratio of gallium nitride in the gallium nitride target is more gallium than nitrogen. For example, nitrogen can be supplied using a nitrogen radical source. The sputtering power supply source may be either a DC power supply source, an RF power supply source, or a pulsed DC power supply source.

The amorphous substrate 100 in the vacuum chamber may be heated. For example, the amorphous substrate 100 can be heated at a temperature higher than or equal to room temperature and lower than 600° C., preferably higher than or equal to 100° C. and lower than or equal to 400° C. This temperature can be applied to an amorphous glass substrate having low heat resistance. Further, this temperature is lower than the deposition temperature in MOCVD or HVPE.

After the vacuum chamber is sufficiently evacuated, the sputtering gas is supplied to the vacuum chamber. Further, a voltage is applied between the amorphous substrate 100 and the gallium nitride target at a predetermined pressure to generate a plasma and the gallium nitride film is deposited.

Although the deposition method of the gallium nitride by sputtering is described, the configurations or conditions of sputtering can be changed as appropriate. In addition, aluminum gallium nitride can be deposited using an aluminum gallium nitride target instead of the gallium nitride target.

The non-nitride semiconductor layer 190 includes a semiconductor other than the compound semiconductor used in the first nitride semiconductor layer 130 and the second nitride semiconductor layer 140. For example, a silicon semiconductor such as amorphous silicon or polysilicon, or an oxide semiconductor such as indium gallium zinc oxide (IGZO), indium aluminum zinc oxide (IAZO), indium gallium aluminum oxide (IGAO), indium gallium oxide (IGO), or zinc oxide (ZnO) can be used for the non-nitride semiconductor layer 190. In addition, the non-nitride semiconductor layer 190 may include not only a channel formation region, but also a source region or a drain region to which an impurity is added.

Silicon oxide (SiOₓ), aluminum oxide (AlOₓ), hafnium oxide (HfOₓ), lanthanum oxide (LaOₓ), silicon nitride (SiNₓ), aluminum nitride (AlNₓ), or the like can be used for the insulating layers 150 and 200. Each of the insulating layers 150 and 200 may be a single film or a laminated film. In addition, the insulating layers 150 and 200 may be formed by separating one insulating film.

A metal such as aluminum (Al), titanium (Ti), platinum (Pt), nickel (Ni), tantalum (Ta), or gold (Au), or alloys thereof can be used for the conductive layers 160, 170, 180, 210, 220, 230, and 250. Each of the conductive layers 160, 170, 180, 210, 220, 230, and 250 may be a single film or a laminated film. Each of the conductive layers 160, 170, 180, 210, 220, and 230 may be formed simultaneously by patterning one conductive film.

The insulating layer 240 preferably flattens the unevenness of the first transistor 11 and the second transistor 12. An organic resin material such as acrylic or polyimide can also be used for the insulating layer 240. The insulating layer 240 may be a single film or a laminated film. When the insulating layer 240 is a laminated film, the insulating layer 240 may contain not only an organic resin material but also an inorganic material such as silicon oxide (SiOₓ) or silicon nitride (SiNₓ).

In the semiconductor device 10, the non-nitride semiconductor layer 190 may be formed after the buffer layer 120, the first nitride semiconductor layer 130, and the second nitride semiconductor layer 140 of the first transistor 11 are formed. Further, the buffer layer 120, the first nitride semiconductor layer 130, and the second nitride semiconductor layer 140 of the first transistor 11 may be formed after the non-nitride semiconductor layer 190 is formed. In the former case, the buffer layer 120 can be formed on a clean surface, and the non-nitride semiconductor layer 190 can be prevented from being exposed during other processes.

As described above, in the semiconductor element 10 according to the present embodiment, even when the first transistor 11 (HEMT) is a normally-on type, the second transistor 12 functions as a switch for the first transistor 11. Thus, the semiconductor element 10 can function as a normally-off type transistor. Further, by adjusting the configuration of the second transistor 12, the semiconductor element 10 can be configured so as not to reduce the current of the first transistor 11 without changing the structure of the first transistor 11. Therefore, the semiconductor element 10 has a structure with a high degree of design freedom.

In addition, although the second transistor 12 is a top-gate transistor in the above description, the configuration of the second transistor 12 is not limited thereto. The second transistor 12 may be a bottom-gate transistor.

### First Modification of First Embodiment

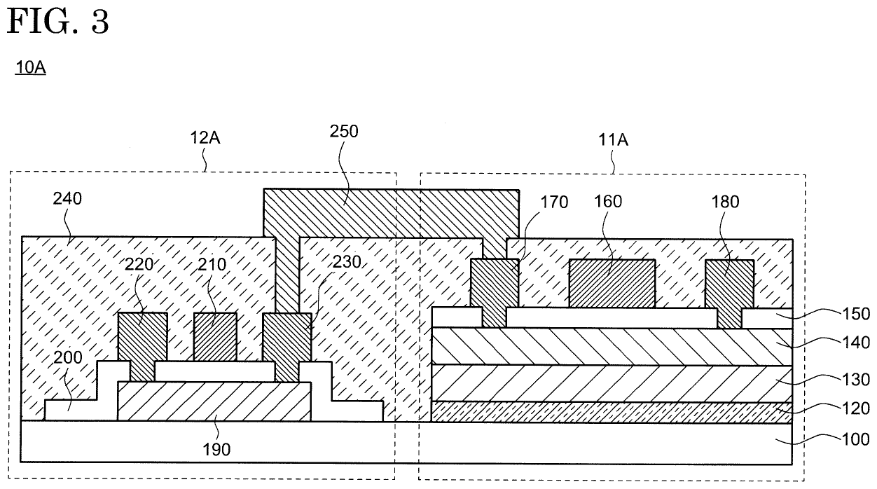

A semiconductor element 10A which is a modification of the semiconductor element 10 according to the present embodiment is described with reference to FIG. 3. In the following description, when a configuration of the semiconductor element 10A is similar to the configuration of the semiconductor element 10, the description of the configuration of the semiconductor element 10A may be omitted.

FIG. 3 is a schematic cross-sectional view showing a configuration of the semiconductor element 10A according to an embodiment of the present invention. As shown in FIG. 3, the semiconductor element 10A includes a first transistor 11A and a second transistor 12A.

The first transistor 11A includes the amorphous substrate 100, the buffer layer 120, the first nitride semiconductor layer 130, the second nitride semiconductor layer 140, the insulating layer 150, and the conductive layers 160, 170, and 180. The buffer layer 120 is provided on the amorphous substrate 100.

The second transistor 12A includes the amorphous substrate 100, the non-nitride semiconductor layer 190, the insulating layer 200, and the conductive layers 210, 220, and 230. The non-nitride semiconductor layer 190 is provided on the amorphous substrate 100.

As shown in FIG. 3, although the first transistor 11A and the second transistor 12A are provided over the same amorphous substrate 100, the semiconductor element 10A has a configuration that does not include the base layer 110. Even in this configuration that does not include the base layer 110, since the first transistor 11A is provided with the buffer layer 120, the first transistor 11A can function as a HEMT.

As described above, in the semiconductor element 10A according to the present modification, even when the first transistor 11A (HEMT) is a normally-on type, the second transistor 12A functions as a switch for the first transistor 11A. Thus, the semiconductor element 10A can function as a normally-off type transistor. Further, by adjusting the configuration of the second transistor 12A, the semiconductor element 10A can be configured so as not to reduce the current of the first transistor 11A without changing the structure of the first transistor 11A. Therefore, the semiconductor element 10A has a structure with a high degree of design freedom.

### Modification 2 of First Embodiment

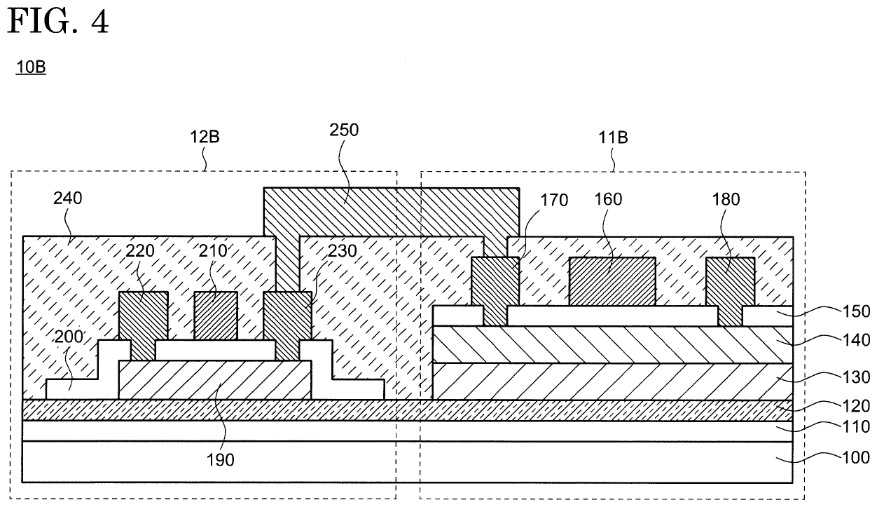

A semiconductor element 10B which is another modification of the semiconductor element 10 according to the present embodiment is described with reference to FIG. 4. In the following description, when a configuration of the semiconductor element 10B is similar to the configuration of the semiconductor element 10, the description of the configuration of the semiconductor element 10B may be omitted.

FIG. 4 is a schematic cross-sectional view showing a configuration of the semiconductor element 10B according to an embodiment of the present invention. As shown in FIG. 4, the semiconductor element 10B includes a first transistor 11B and a second transistor 12B.

The first transistor 11B includes the amorphous substrate 100, the base layer 110, the buffer layer 120, the first nitride semiconductor layer 130, the second nitride semiconductor layer 140, the insulating layer 150, and the conductive layers 160, 170, and 180.

The second transistor 12B includes the amorphous substrate 100, the base layer 110, the buffer layer 120, the non-nitride semiconductor layer 190, the insulating layer 200, and the conductive layers 210, 220, and 230. The buffer layer 120 is provided on the base layer 110. The non-nitride semiconductor layer 190 is provided on the buffer layer 120.

As shown in FIG. 4, the first transistor 11B and the second transistor 12B include the base layer 110 and the buffer layer 120 as common layers. In the semiconductor element 10B, an insulating material is used for the buffer layer 120, not a conductive material. In this way, even when the second transistor 12B has a configuration including a common buffer layer 120, the buffer layer 120 has insulating properties, so that the second transistor 12B has a normally-off type property. Further, since the buffer layer 120 is commonly provided on the amorphous substrate 100, it is not necessary to pattern the buffer layer 120, and the process cost can be suppressed. Furthermore, since the area of the buffer layer 120 is increased, the heat dissipation characteristics and electrostatic discharge characteristics of the semiconductor element 10B can be improved.

As described above, in the semiconductor element 10B according to the present modification, even when the first transistor 11B (HEMT) is a normally-on type, the second transistor 12B functions as a switch for the first transistor 11B. Thus, the semiconductor element 10B can function as a normally-off type transistor. Further, by adjusting the configuration of the second transistor 12B, the semiconductor element 10B can be configured so as not to reduce the current of the first transistor 11B without changing the structure of the first transistor 11B. Therefore, the semiconductor element 10B has a structure with a high degree of design freedom.

### Modification 3 of First Embodiment

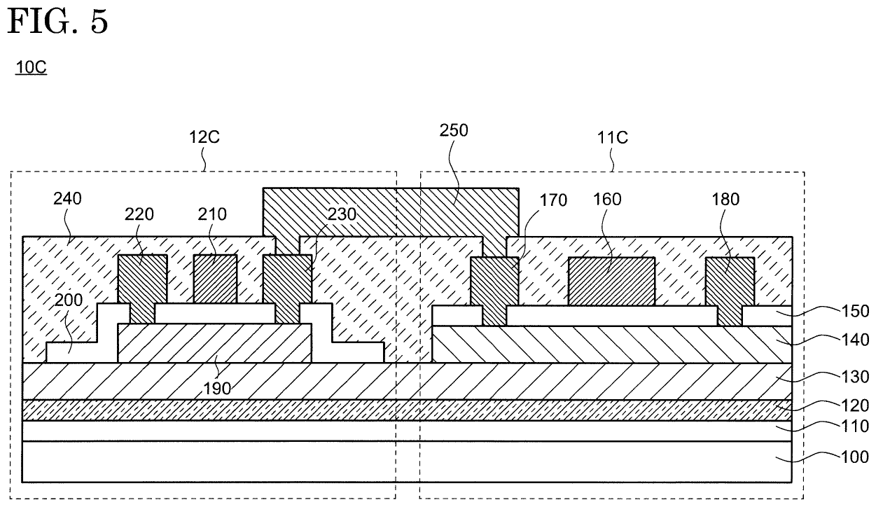

A semiconductor element 10C which is another modification of the semiconductor element 10 according to the present embodiment is described with reference to FIG. 5. In the following, when a configuration of the semiconductor element 10C is similar to the configuration of the semiconductor element 10, the description of the configuration of the semiconductor element 10C may be omitted.

FIG. 5 is a schematic cross-sectional view showing a configuration of the semiconductor device 10C according to an embodiment of the present invention. As shown in FIG. 5, the semiconductor device 10C includes a first transistor 11C and a second transistor 12C.

The first transistor 11C includes the amorphous substrate 100, the base layer 110, the buffer layer 120, the first nitride semiconductor layer 130, the second nitride semiconductor layer 140, the insulating layer 150, and the conductive layers 160, 170, and 180.

The second transistor 12C includes the amorphous substrate 100, the base layer 110, the buffer layer 120, the first nitride semiconductor layer 130, the non-nitride semiconductor layer 190, the insulating layer 200, and the conductive layers 210, 220, and 230. The buffer layer 120 is provided on the base layer 110. The first nitride semiconductor layer 130 is provided on the buffer layer 120. The non-nitride semiconductor layer 190 is provided on the first nitride semiconductor layer 130.

As shown in FIG. 5, the first transistor 11C and the second transistor 12C include the base layer 110, the buffer layer 120, and the first nitride semiconductor layer 130 as common layers. In the semiconductor device 10C, a conductive material or an insulating material is used for the buffer layer 120. In this way, even when the second transistor 12C has a configuration including the common first nitride semiconductor layer 130, the first nitride semiconductor layer has insulating properties, so that the second transistor 12C has a normally-off type property. Further, since the buffer layer 120 and the first nitride semiconductor layer 130 are commonly provided on the amorphous substrate 100, it is not necessary to pattern the buffer layer 120 and the first nitride semiconductor layer 130, and the process cost can be suppressed. Furthermore, since the area of the buffer layer 120 and the first nitride semiconductor layer 130 are increased, the heat dissipation characteristics and electrostatic discharge characteristics of the semiconductor device 10C are improved.

As described above, in the semiconductor element 10C according to this modification, even if the first transistor 11C (HEMT) is a normally-on type, the second transistor 12C functions as a switch for the first transistor 11C. Thus, the semiconductor element 10C can function as a normally-off type transistor. Further, by adjusting the configuration of the second transistor 12C, the semiconductor element 10C can be configured so as not to reduce the current of the first transistor 11C without changing the structure of the first transistor 11C. Therefore, the semiconductor element 10C has a structure with a high degree of design freedom.

### Fourth Modification of First Embodiment

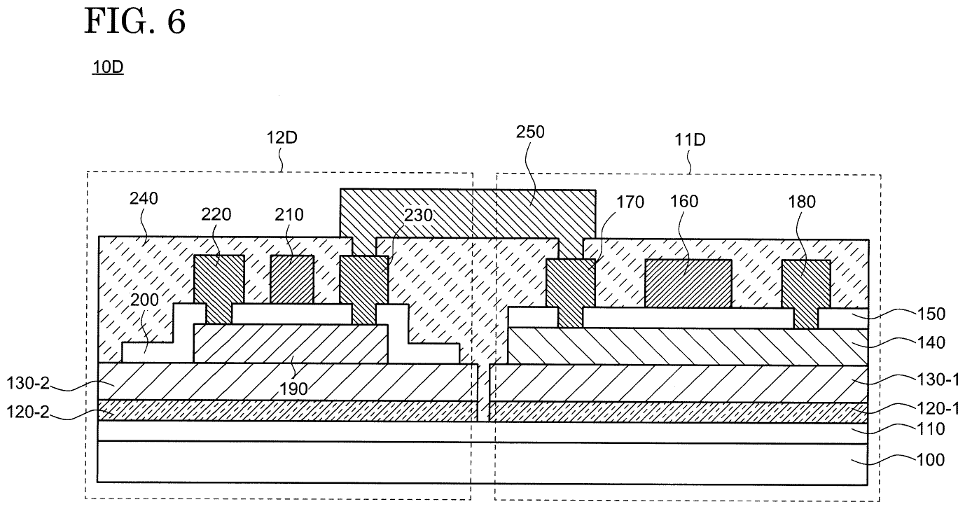

A semiconductor element 10D which is another modification of the semiconductor element 10 according to the present embodiment is described with reference to FIG. 6. In the following description, when a configuration of the semiconductor element 10D is similar to the configuration of the semiconductor element 10 or the semiconductor element 10C, the description of the configuration of the semiconductor element 10D may be omitted.

FIG. 6 is a schematic cross-sectional view showing a configuration of the semiconductor device 10D according to an embodiment of the present invention. As shown in FIG. 6, the semiconductor device 10D includes a first transistor 11D and a second transistor 12D.

The first transistor 11D includes the amorphous substrate 100, the base layer 110, a first buffer layer 120-1, a first-1 nitride semiconductor layer 130-1, the second nitride semiconductor layer 140, the insulating layer 150, and the conductive layers 160, 170, and 180.

The second transistor 12D includes the amorphous substrate 100, the base layer 110, a second buffer layer 120-2, a first-2 nitride semiconductor layer 130-2, the non-nitride semiconductor layer 190, the insulating layer 200, and the conductive layers 210, 220, and 230.

The first buffer layer 120-1 and the second buffer layer 120-2 are formed by separating one buffer layer. The first-1 nitride semiconductor layer 130-1 and the first-2 nitride semiconductor layer 130-2 are formed by separating one first nitride semiconductor layer. An insulating layer 240 is filled between the first transistor 11D and the second transistor 12D. Therefore, in the semiconductor device 10D, since the first transistor 11D and the second transistor 12D are separated, unnecessary interference between the first transistor 11D and the second transistor 12D is suppressed.

As described above, in the semiconductor element 10D according to the present modification, even when the first transistor 11D (HEMT) is a normally-on type, the second transistor 12D functions as a switch for the first transistor 11D. Thus, the semiconductor element 10D can function as a normally-off type transistor. Further, by adjusting the configuration of the second transistor 12D, the semiconductor element 10D can be configured so as not to reduce the current of the first transistor 11D without changing the structure of the first transistor 11D. Therefore, the semiconductor element 10D has a structure with a high degree of design freedom.

### Second Embodiment

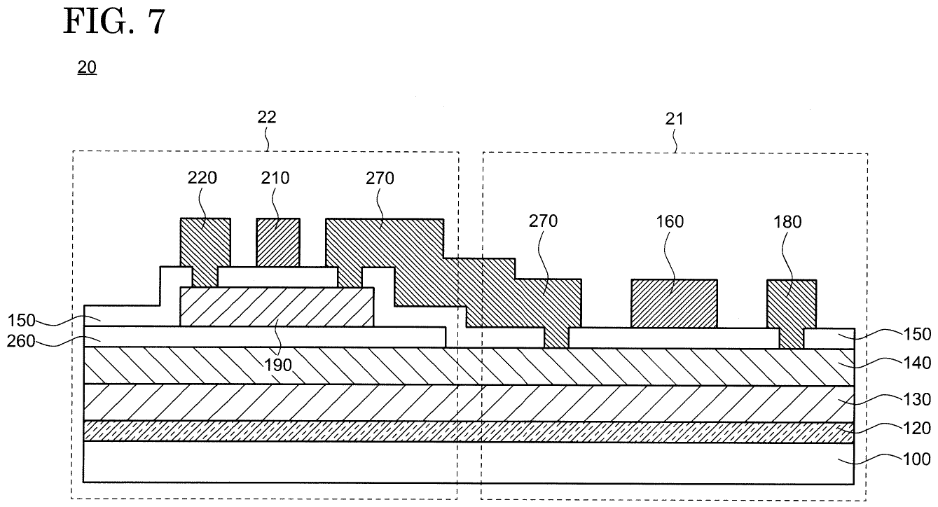

FIG. 7 is a schematic cross-sectional view showing a configuration of a semiconductor element 20 according to an embodiment of the present invention. As shown in FIG. 7, the semiconductor element 20 includes a first transistor 21 and a second transistor 22. In the following description, when a configuration of the semiconductor element 20 is similar to the configuration of the semiconductor element 10, the description of the configuration of the semiconductor element 20 may be omitted.

The first transistor 21 includes the amorphous substrate 100, the buffer layer 120, the first nitride semiconductor layer 130, the second nitride semiconductor layer 140, the insulating layer 150, and conductive layers 160, 180, and 270. The conductive layers 210, 220, and 270 are provided on the insulating layer 150. Further, openings are provided in the insulating layer 150, and the conductive layers 180 and 270 are electrically connected to the second nitride semiconductor layer 140 through the openings.

The second transistor 22 includes the amorphous substrate 100, the buffer layer 120, the first nitride semiconductor layer 130, the second nitride semiconductor layer 140, an insulating layer 260, a non-nitride semiconductor layer 190, an insulating layer 150, and conductive layers 210, 220, and 270. An insulating layer 260 is provided on the second nitride semiconductor layer 140. The non-nitride semiconductor layer 190 is provided on the insulating layer 260. The conductive layers 210, 220, and 270 are provided on the insulating layer 150. Further, openings are provided in the insulating layer 150, and the conductive layers 220 and 270 are electrically connected to the non-nitride semiconductor layer 190 through the openings.

As shown in FIG. 7, the first transistor 21 and the second transistor 22 are provided over the same amorphous substrate 100. The first transistor 21 and the second transistor 22 also include the buffer layer 120, the first nitride semiconductor layer 130, the second nitride semiconductor layer 140, and the insulating layer 150 as common layers. In each of the first transistor 21 and the second transistor 22, the insulating layer 150 functions as a gate insulating film. The first transistor 21 and the second transistor 22 also include the conductive layer 270 as a common layer. The conductive layer 270 functions as a source electrode or a drain electrode of each of the first transistor 21 and the second transistor 22, and also functions as a connection electrode that electrically connects the first transistor 21 and the second transistor 22.

The insulating layer 260 can electrically insulate the second nitride semiconductor layer 140 from the non-nitride semiconductor layer 190. Therefore, the second transistor 22 has a normally-off property without being affected by the second nitride semiconductor layer 140. A silicon nitride (SiNₓ) film or the like can be used for the insulating layer 260. Further, a laminated film of a silicon oxide (SiOₓ) film and a silicon nitride (SiNₓ) film can be used as the insulating layer 260.

The same material as the conductive layers 160, 180, 210, and 220 can be used for the conductive layer 270. The conductive layer 270 can be formed simultaneously with the conductive layers 160, 180, 210, and 220 by patterning one conductive film. As described above, the conductive layer 270 can electrically connect the first transistor 21 and the second transistor 22. Therefore, since it is not necessary to provide another connection electrode in the semiconductor element 20, the process cost can be reduced.

As described above, in the semiconductor element 20 according to the present embodiment, even when the first transistor 21 (HEMT) is a normally-on type, the second transistor 22 functions as a switch for the first transistor 21. Thus, the semiconductor element 20 can function as a normally-off type transistor. Further, by adjusting the configuration of the second transistor 22, the semiconductor element 20 can be configured so as not to reduce the current of the first transistor 21 without changing the structure of the first transistor 21. Therefore, the semiconductor element 20 has a structure with a high degree of design freedom.

### Modification 1 of Second Embodiment

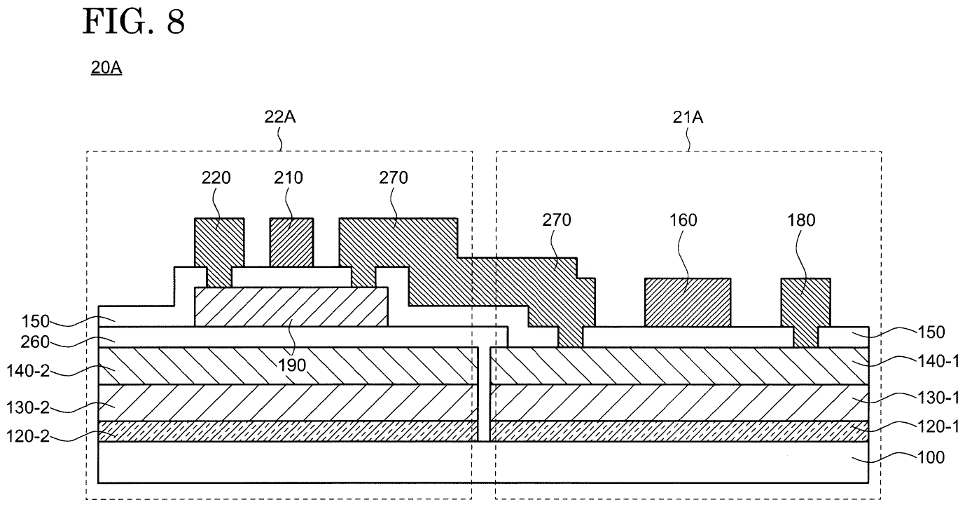

A semiconductor element 20A which is a modification of the semiconductor element 20 according to the present embodiment is described with reference to FIG. 8. In the following description, when a configuration of the semiconductor element 20A is similar to the configuration of the semiconductor element 20, the description of the configuration of the semiconductor element 20A may be omitted.

FIG. 8 is a schematic cross-sectional view showing a configuration of the semiconductor element 20A according to an embodiment of the present invention. As shown in FIG. 8, the semiconductor element 20A includes a first transistor 21A and a second transistor 22A.

The first transistor 21A includes the amorphous substrate 100, the first buffer layer 120-1, the first-1 nitride semiconductor layer 130-1, a second-1 nitride semiconductor layer 140-1, the insulating layer 150, and the conductive layers 160, 180, and 270.

The second transistor 22A includes the amorphous substrate 100, the first-2 nitride semiconductor layer 130-2, a second-2 nitride semiconductor layer 140-2, the insulating layer 260, the non-nitride semiconductor layer 190, the insulating layer 150, and the conductive layers 210, 220, and 270.

The first buffer layer 120-1 and the second buffer layer 120-2 are formed by separating one buffer layer. The first-1 nitride semiconductor layer 130-1 and the first-2 nitride semiconductor layer 130-2 are formed by separating one first nitride semiconductor layer. The second-1 nitride semiconductor layer 140-1 and the second-2 nitride semiconductor layer 140-2 are formed by separating one second nitride semiconductor layer. The insulating layer 260 is filled between the first transistor 21A and the second transistor 22A. Therefore, in the semiconductor element 20A, since the first transistor 21A and the second transistor 22A are separated from each other, unnecessary interference between the first transistor 21A and the second transistor 22D is suppressed.

As described above, in the semiconductor element 20A according to this modification, even when the first transistor 21A (HEMT) is a normally-on type, the second transistor 22A functions as a switch for the first transistor 21A. Thus, the semiconductor element 20A can function as a normally-off type transistor. Further, by adjusting the configuration of the second transistor 22A, the semiconductor element 20A can be configured so as not to reduce the current of the first transistor 21A without changing the structure of the first transistor 21A. Therefore, the semiconductor element 20A has a structure with a high degree of design freedom.

### Modification 2 of Second Embodiment

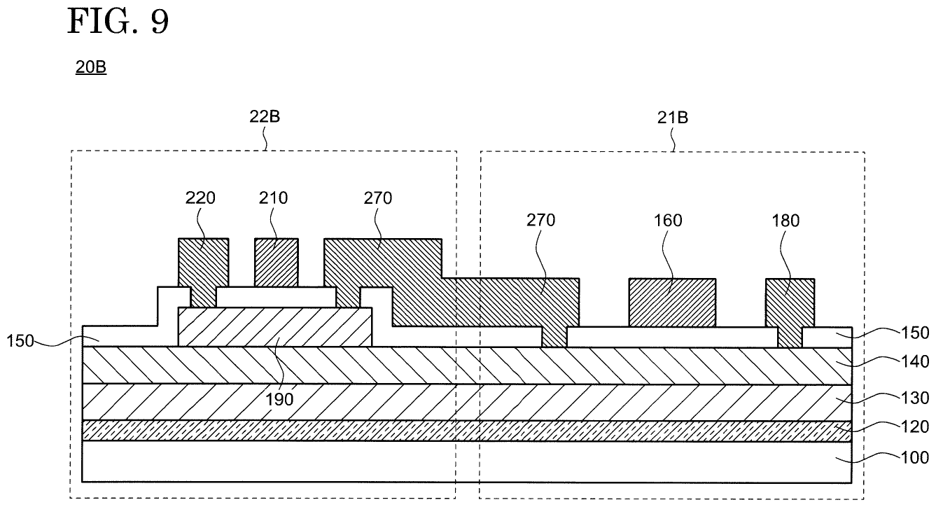

A semiconductor element 20B which is another modification of the semiconductor element 20 according to the present embodiment is described with reference to FIG. 9. In the following description, when a configuration of the semiconductor element 20B is similar to the configuration of the semiconductor element 20, the description of the configuration of the semiconductor element 20B may be omitted.

FIG. 9 is a schematic cross-sectional view showing a configuration of the semiconductor element 20B according to an embodiment of the present invention. As shown in FIG. 9, the semiconductor element 20B includes a first transistor 21B and a second transistor 22B.

The first transistor 21B includes the amorphous substrate 100, the buffer layer 120, the first nitride semiconductor layer 130, the second nitride semiconductor layer 140, the insulating layer 150, and the conductive layers 160, 180, and 270.

The second transistor 22B includes the amorphous substrate 100, the buffer layer 120, the first nitride semiconductor layer 130, the second nitride semiconductor layer 140, the non-nitride semiconductor layer 190, the insulating layer 150, and the conductive layers 210, 220, and 270. The non-nitride semiconductor layer 190 is provided on the second nitride semiconductor layer 140.

As shown in FIG. 9, although the first transistor 21B and the second transistor 22B are provided over the same amorphous substrate 100, the semiconductor element 20B has a configuration that does not include the insulating layer 260 between the second nitride semiconductor layer 140 and the non-nitride semiconductor layer 190. Even in the configuration that does not include the insulating layer 260, when the insulating property of the second nitride semiconductor layer 140 is high, the leakage current between the non-nitride semiconductor layer 190 and the second nitride semiconductor layer 140 is suppressed. Therefore, the second transistor 22B can function as a normally-off type transistor.

As described above, in the semiconductor element 20B according to the present modification, even when the first transistor 21B (HEMT) is a normally-on type, the second transistor 22B functions as a switch for the first transistor 21B. Thus, the semiconductor element 20B can function as a normally-off type transistor. Further, by adjusting the configuration of the second transistor 22B, the semiconductor element 20B can be configured to not reduce the current of the first transistor 21B without changing the structure of the first transistor 21B. Therefore, the semiconductor element 20B has a structure with a high degree of design freedom.

### Third Embodiment

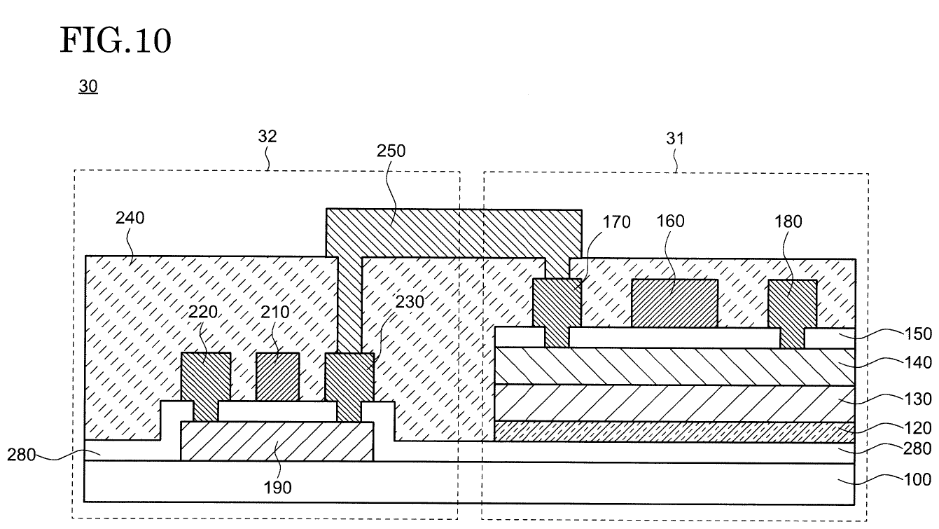

FIG. 10 is a schematic cross-sectional view showing a configuration of a semiconductor element 30 according to an embodiment of the present invention. As shown in FIG. 10, the semiconductor element 30 includes a first transistor 31 and a second transistor 32. In the following description, when the configuration of the semiconductor element 30 is similar to the configuration of the semiconductor element 10, the description of the configuration of the semiconductor element 30 may be omitted.

The first transistor 31 includes the amorphous substrate 100, an insulating layer 280, the buffer layer 120, the first nitride semiconductor layer 130, the second nitride semiconductor layer 140, the insulating layer 150, and the conductive layers 160, 170, and 180. The insulating layer 280 is provided on the amorphous substrate 100. The buffer layer 120 is provided on the insulating layer 280.

The second transistor 32 includes the amorphous substrate 100, the non-nitride semiconductor layer 190, the insulating layer 280, and the conductive layers 210, 220, and 230. The non-nitride semiconductor layer 190 is provided on the amorphous substrate 100. The insulating layer 280 is provided on the non-nitride semiconductor layer 190 and covers a top surface and a side surface of the non-nitride semiconductor layer 190. Openings are provided in the insulating layer 280, and the conductive layers 220 and 230 are electrically connected to the non-nitride semiconductor layer 190 through the openings.

As shown in FIG. 10, the first transistor 31 and the second transistor 32 are provided over the same amorphous substrate 100. The first transistor 31 and the second transistor 32 include the insulating layer 280 as a common layer. In the first transistor 31, the insulating layer 280 functions as a base film. In the second transistor 32, the insulating layer 280 functions as a gate insulating film.

The same material as the insulating layer 150 can be used for the insulating layer 280.

In the semiconductor element 30, the buffer layer 120, the first nitride semiconductor layer 130, and the second nitride semiconductor layer 140 of the first transistor 31 are formed after the non-nitride semiconductor layer 190 of the second transistor 32 is formed. That is, the non-nitride semiconductor layer 190 is formed, and then the non-nitride semiconductor layer 190 is covered with an insulating film constituting the insulating layer 280. Next, the buffer layer 120, the first nitride semiconductor layer 130, and the second nitride semiconductor layer 140 are formed on the insulating film. Therefore, in the formation of the buffer layer 120, the first nitride semiconductor layer 130, and the second nitride semiconductor layer 140, the non-nitride semiconductor layer 190 can be protected by the insulating film.

As described above, in the semiconductor element 30 according to the present embodiment, even when the first transistor 31 (HEMT) is a normally-on type, the second transistor 32 functions as a switch for the first transistor 31. Thus, the semiconductor element 30 can function as a normally-off type transistor. Further, by adjusting the configuration of the second transistor 32, the semiconductor element 30 can be configured so as not to reduce the current of the first transistor 31 without changing the structure of the first transistor 31. Therefore, the semiconductor element 30 has a structure with a high degree of design freedom.

### Fourth Embodiment

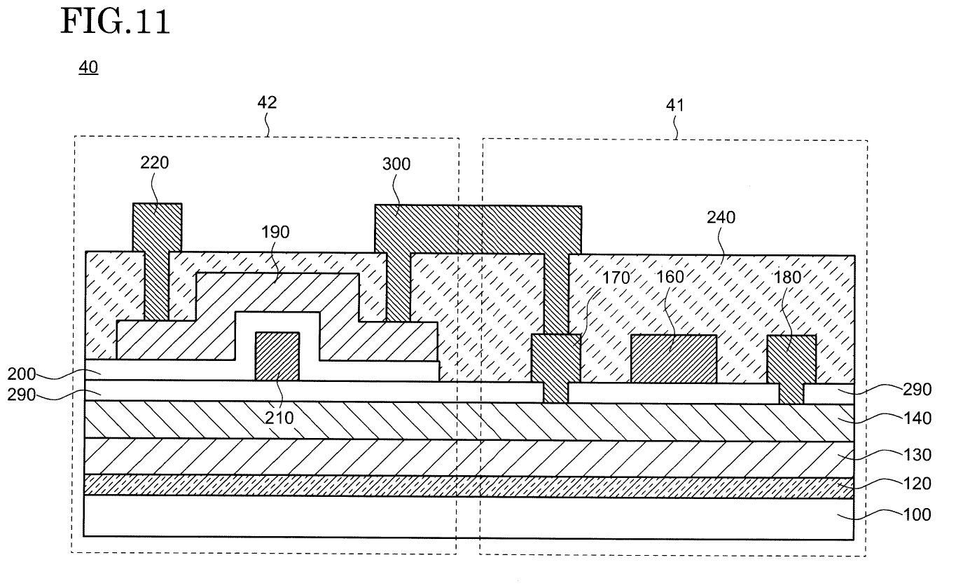

FIG. 11 is a schematic cross-sectional view showing a configuration of a semiconductor element 40 according to an embodiment of the present invention. As shown in FIG. 11, the semiconductor element 40 includes a first transistor 41 and a second transistor 42. In the following description, when the configuration of the semiconductor element 40 is similar to the configuration of the semiconductor element 10, the description of the configuration of the semiconductor element 40 may be omitted.

The first transistor 41 includes the amorphous substrate 100, the buffer layer 120, the first nitride semiconductor layer 130, the second nitride semiconductor layer 140, an insulating layer 290, and the conductive layers 160, 170, and 180. The insulating layer 290 is provided on the second nitride semiconductor layer 140. The conductive layers 160, 170, and 180 are provided on the insulating layer 290. Openings are provided in the insulating layer 290, and the conductive layers 170 and 180 are electrically connected to the second nitride semiconductor layer 140 through the openings.

The second transistor 42 includes the amorphous substrate 100, the buffer layer 120, the first nitride semiconductor layer 130, the second nitride semiconductor layer 140, the insulating layer 290, the conductive layer 210, the insulating layer 200, the non-nitride semiconductor layer 190, and conductive layers 220 and 300. The insulating layer 290 is provided on the second nitride semiconductor layer 140. The conductive layer 210 is provided on the insulating layer 290. The insulating layer 200 is provided on the conductive layer 210. The non-nitride semiconductor layer 190 is provided on the insulating layer 200.

As shown in FIG. 11, the first transistor 41 and the second transistor 42 are provided on the same amorphous substrate 100. The first transistor 41 and the second transistor 42 include the buffer layer 120, the first nitride semiconductor layer 130, and the second nitride semiconductor layer 140 as common layers. The conductive layers 160, 170, and 180 of the first transistor 41 and the non-nitride semiconductor layer 190 of the second transistor 42 are covered by the insulating layer 240. The insulating layer 240 has openings through which the conductive layer 170 of the first transistor 41 and the non-nitride semiconductor layer 190 of the second transistor 42 are exposed. The conductive layers 220 and 300 are provided in the openings of the second transistor 42, and the conductive layers 220 and 300 are electrically connected to the non-nitride semiconductor layer 190 through the openings. That is, the conductive layers 220 and 300 function as a source electrode or a drain electrode of the second transistor 42. Further, the conductive layer 300 is electrically connected to the conductive layer 170 through the opening of the first transistor 41. That is, the conductive layer 300 also functions as a connection electrode that electrically connects the first transistor 41 and the second transistor 42.

In the second transistor 42, a gate electrode is located below the non-nitride semiconductor layer 190, and a source electrode and a drain electrode are located over the non-nitride semiconductor layer 190. That is, the second transistor 42 is a bottom-gate transistor. Thus, a bottom-gate transistor can be used as the second transistor 42 in the semiconductor element 40.

The insulating layer 290 functions as a gate insulating film of the first transistor 41, and can electrically insulate the second nitride semiconductor layer 140 and the non-nitride semiconductor layer 190 from each other in the second transistor 42. Therefore, the second transistor 22 has a normally-off property without being affected by the second nitride semiconductor layer 140. A silicon nitride (SiNₓ) film or the like can be used as the insulating layer 290. Further, a laminated film of a silicon oxide (SiOₓ) film and a silicon nitride (SiNₓ) film can be used as the insulating layer 290.

The same material as the conductive layer 220 can be used for the conductive layer 300.

As described above, in the semiconductor element 40 according to the present embodiment, even when the first transistor 41 (HEMT) is a normally-on type, the second transistor 42 functions as a switch for the first transistor 41. Thus, the semiconductor element 40 can function as a normally-off type transistor. Further, by adjusting the configuration of the second transistor 42, the semiconductor element 40 can be configured so as not to reduce the current of the first transistor 41 without changing the structure of the first transistor 41. Therefore, the semiconductor element 40 has a structure with a high degree of design freedom.

Each of the embodiments described above as the embodiments of the present invention can be appropriately combined and implemented as long as no contradiction is caused. Further, the addition, deletion, or design change of components, or the addition, deletion, or condition change of processes as appropriate by those skilled in the art based on each of the embodiments are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor element, comprising;
a first transistor over an amorphous substrate, comprising:
a buffer layer;
a first nitride semiconductor layer over the buffer layer;
a second nitride semiconductor layer forming a heterojunction with the first nitride semiconductor layer; and
a first conductive layer in contact with the second nitride semiconductor layer, and functioning as a source electrode or a drain electrode; and
a second transistor over the amorphous substrate, comprising:
a non-nitride semiconductor layer; and
a second conductive layer in contact with the non-nitride semiconductor layer, and functioning as a source electrode or a drain electrode,
wherein the first conductive layer is electrically connected to the second conductive layer.

2. The semiconductor element according to claim 1, wherein the first conductive layer is electrically connected to the second conductive layer through a third conductive layer provided over the first transistor and the second transistor.

3. The semiconductor element according to claim 1, wherein the first conductive layer is a same layer as the second conductive layer.

4. The semiconductor element according to claim 1, wherein the second transistor further comprises the buffer layer below the non-nitride semiconductor layer.

5. The semiconductor element according to claim 4, wherein the second transistor further comprises the first nitride semiconductor layer over the buffer layer.

6. The semiconductor element according to claim 5,
wherein the buffer layer and the first nitride semiconductor layer are separated from each other between the first transistor and the second transistor, and
wherein an insulating layer is filled between the first transistor and the second transistor.

7. The semiconductor element according to claim 6, wherein the insulating layer is provided over the first conductive layer and the second conductive layer.

8. The semiconductor element according to claim 7, wherein the buffer layer comprises at least one selected from the group consisting of titanium, graphene, zinc oxide, and aluminum nitride.

9. The semiconductor element according to claim 7, wherein the amorphous substrate is an amorphous glass substrate.

10. The semiconductor element according to claim 6, wherein the insulating layer is provided below the non-nitride semiconductor layer.

11. The semiconductor element according to claim 10, wherein the buffer layer comprises at least one selected from the group consisting of titanium, graphene, zinc oxide, and aluminum nitride.

12. The semiconductor element according to claim 10, wherein the amorphous substrate is an amorphous glass substrate.

13. The semiconductor element according to claim 1,
wherein the first transistor further comprises an insulating layer below the buffer layer, and
wherein the second transistor further comprises the insulating layer functioning as a gate insulating layer over the non-nitride semiconductor layer.

14. The semiconductor element according to claim 13, wherein the buffer layer comprises at least one selected from the group consisting of titanium, graphene, zinc oxide, and aluminum nitride.

15. The semiconductor element according to claim 13, wherein the amorphous substrate is an amorphous glass substrate.

16. The semiconductor element according to claim 1,
wherein the second transistor further comprises an insulating layer below the non-nitride semiconductor layer, and
wherein the first transistor further comprises the insulating layer functioning as a gate insulating layer over the second nitride semiconductor layer.

17. The semiconductor element according to claim 16, wherein the buffer layer comprises at least one selected from the group consisting of titanium, graphene, zinc oxide, and aluminum nitride.

18. The semiconductor element according to claim 16, wherein the amorphous substrate is an amorphous glass substrate.

19. The semiconductor element according to claim 1, wherein the first nitride semiconductor layer comprises gallium nitride.

20. The semiconductor element according to claim 1, wherein the non-nitride semiconductor layer comprises silicon or oxide semiconductor.
